(19) United States
(12) Patent Application Publication
(10) Pub. No.: US 2007/0281464 A1
(43) Pub. Date: Dec. 6, 2007

(54) Multi-layer circuit board with fine pitches and fabricating method thereof

(76) Inventor: Shih-Ping Hsu, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 11/421,760

(22) Filed: Jun. 1, 2006

(51) Int. Cl. H01L 21/4763

(52) U.S. Cl. 438/624

(57) ABSTRACT

A method for fabricating a multi-layer circuit board with fine pitches is provided. First, a plurality of conductive pads is disposed on a core circuit board. Next, a first dielectric layer and a second dielectric are formed on the core circuit board, in which a plurality of pattern openings are formed in the second dielectric layer and a plurality of vias within the first dielectric layer, wherein the vias are located at the openings corresponding to the contact pads. Next, a seed layer is disposed on the pattern openings and vias and a conductive metal layer is disposed on the seed layer via an electroplating process for forming conductive circuits in each pattern opening and conductive via in each via. Finally, removing the electroplated conductive metal layer and the seed layer over the surface of the second dielectric layer, and form a separation for each conductive circuit at each opening.

### BACKGROUND OF THE INVENTION

1. Field of the Invention

The present invention relates to a method of fabricating a multi-layer circuit board, and more particularly, to a method of fabricating a multi-layer circuit board with fine pitches.

2. Description of the Prior Art

In the past, various build-up layer methods of high-density IC package substrates and printed circuit boards for achieving finer pitch and multiple layers have been disclosed, including laminations of dielectric films, resin-coated copper (RCC), and prepreg.

Recently, a more advanced build-up method has been introduced by providing an insulating core layer with completed upper circuit layers and lower circuit layers, in which the upper and lower circuit layers are electrically connected. To establish the connection between the upper and lower circuit layers, a plurality of plated though holes (PTH) are formed in the core layer to connect upper and lower circuit layers. And then utilizing a laminating process to form a dielectric layer onto the core layer, and forming a plurality of vias by laser drilling on the dielectric layer to expose the contact pads of circuit layers. Next, a seed layer is formed over the surface of the dielectric layer, and then utilizing a photolithography process to form patterned photoresist layer with recesses to expose the vias. Fabricating an electroplating process, a conductive material is formed into the via and the recess of patterned photoresist layer, and then removing the photoresist layer and the exposed seed layer under photoresist layer, a build-up circuit layer is formed and the entire fabrication process is referred to as a semi additive process (SAP).

In general, packaging substrates and printed circuit boards that utilize the SAP methods are able to achieve precise fine pitches with line-width/line-space (L/S) of 20 μm/20 μm, in which the shape of the lines are able to obtain good resistance control and electrical properties. Eventually, the build-up method can be applied to various higher-level printed circuit boards such as flip chip IC packaging substrate.

Nevertheless, numerous difficulties with this technique are yet to be solved as is evident by the various disadvantages that still exist with SAP fabrication. One disadvantage occurs as the lines get finer, such as reaching a L/S of 10 μm/10 μm. At this point the integration of conductive lines and dielectric layers unavoidably becomes much worse, thereby causing problems such as cracks or delaminations. Additionally, as the circuit layout get into fine pitches, the photoresist utilized during fabrication processes are easily trapped within the space between each line, thereby affecting the quality and electrical property of the product. Moreover, the etching process utilized during standard SAP processes for removing the seed layer influences the precision of the shape and size (line width) of the fine lines.

### SUMMARY OF THE INVENTION

It is therefore an objective of the present invention to provide a method of fabricating multi-layer circuit board with fine pitches for solving the above-mentioned problems.

According to the present invention, a method of fabricating a multi-layer circuit board with fine pitches comprising: providing a core substrate, wherein the core substrate comprises a plurality of conductive pads thereon; forming a first dielectric layer over the surface of the core substrate; forming a second dielectric layer over the surface of the first dielectric layer; forming a plurality of patterned openings within the second dielectric layer; forming a plurality of vias within the first dielectric layer, wherein the vias are located at the openings corresponding to the contact pads; forming a seed layer on the surface of the second dielectric layer, the pattern openings, and the vias; electroplating a conductive metal layer layer on the seed layer to form conductive circuits in each pattern opening and conductive vias in each vias; and removing the electroplated conductive metal layer and the seed layer over the surface of the second dielectric layer for forming a separation for each conductive circuit at each patterned opening.

Another objective of the present invention is to provide a build-up layer circuit board with fine pitches. The build-up layer circuit board comprising: a core substrate having a plurality of conductive pads thereon; a first dielectric layer formed on the surface of the core substrate; a plurality of conductive vias formed on the first dielectric layer, wherein the vias are corresponding to the contact pads; a second dielectric layer formed on the surface of the first dielectric layer, wherein the second dielectric layer has a plurality of patterned openings and the patterned openings further include circuits therein; and the circuits are electrically connected to the contact pads through the conductive vias.

By providing a method of forming a plurality of pattern openings and vias within a dielectric layer and depositing conductive metals into each patterned opening and via, the present invention is able to achieve a packaging substrate with much finer pitch, a simplified fabrication process, lower costs, and an increase in the overall product yield.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 8 are perspective diagrams showing a method of fabricating a multi-layer circuit board with fine pitches according to the first embodiment of the present invention.

FIG. 9 is a perspective diagram showing the build-up circuit board with fine pitches of the multi-layer circuit board according to the present invention.

FIG. 10 is a perspective diagram showing the build-up circuit board with fine pitches on both sides of the multi-layer circuit board according to the present invention.

### DETAILED DESCRIPTION

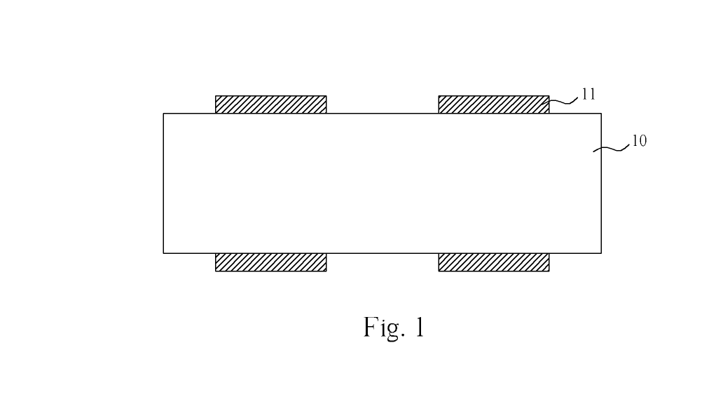

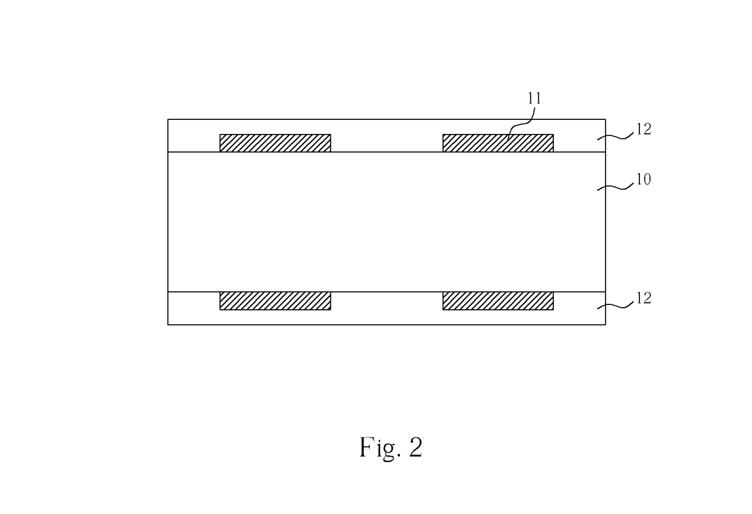

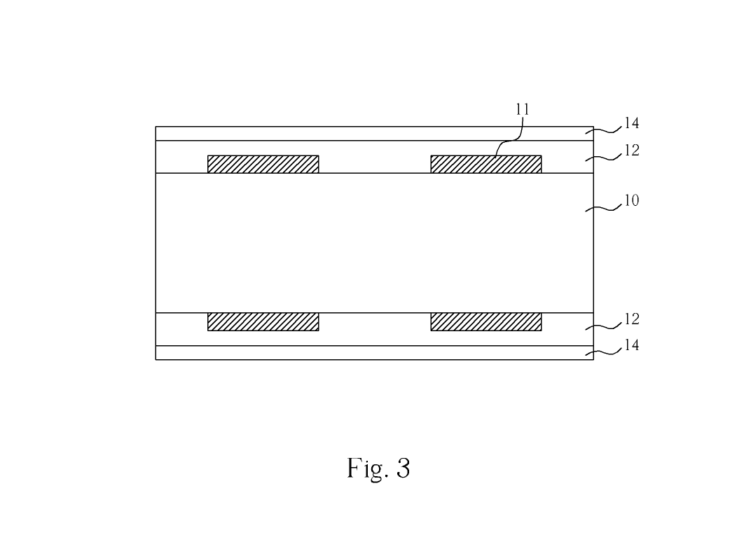

Please refer to FIG. 1 through FIG. 8. FIG. 1 through FIG. 8 are perspective diagrams showing a method of fabricating a multi-layer circuit board with fine pitches according to the first embodiment of the present invention. As shown in FIG. 1, a core substrate 10 is provided, in which a plurality of conductive pads 11 are included over the surface of the substrate 10. Preferably, the core substrate is a double layer circuit board, a multi-layer circuit board, an organic insulating substrate, an inorganic insulating substrate, a ceramic substrate, or a metal substrate. Next, a first dielectric layer 12 is formed over the surface of the core substrate 10, as shown in FIG. 2. Next, a second dielectric layer 14 is formed over the surface of the first dielectric layer 12 as shown in FIG. 3, in which the first dielectric layer 12 and the second dielectric layer 14 can be comprised of photosensitive or non-photosensitive materials and are formed utilizing processes including: laminating, coating, vacuum compressing, or printing. Alternatively, a composite layer (not shown) can be formed over the surface of the core substrate 10, in which the composite layer includes the first dielectric layer 12 and the second dielectric layer 14. Next a laminating process is performed by laminating the first dielectric layer 12 of the composite layer to the core substrate 10 to form the circuit board, as shown in FIG. 3.

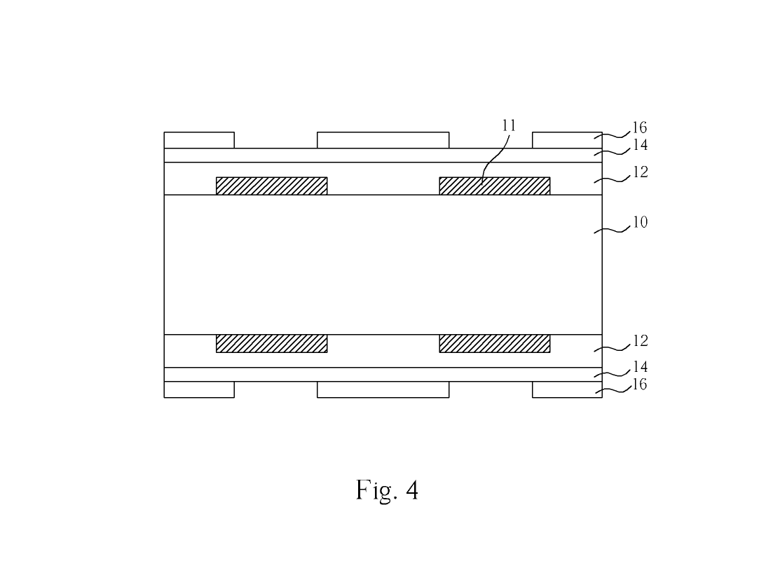

Next, a patterned photomask 16 is formed over the surface of the second dielectric layer 14 to define the location of the patterned openings and vias as shown in FIG. 4. By utilizing the patterned resistive 16, a circuit pattern transfer is performed by processes including: dry etching, reaction ion etching, laser drilling, chemical development, or a combination of these processes to form a plurality of pattern openings 18 within the second dielectric layer 14 and a plurality of vias 20 within the first dielectric layer 12, wherein the vias 20 are located at the openings 18 corresponding to the contact pads 11. For instance, when the second dielectric layer 14 is comprised of photosensitive material, a photolithography process is performed utilizing the photomask as the patterned resistive 16 to form the pattern openings 18. When the first dielectric layer 12 and the second dielectric layer 14 are both comprised of photosensitive material, a precuring process is performed on the first dielectric layer 12 to turn the first dielectric layer 12 into a photo-stopping layer. A photolithography process is performed to the second dielectric layer 14, in which the photolithography process is stopped at the surface of the first dielectric layer 12, due to the photo-stopping layer. Next, a drilling process is performed to penetrate the first dielectric layer 12 to form the vias 20. When the first dielectric layer 12 is comprised of non-photosensitive material and the second dielectric layer 14 is comprised of photosensitive material, the first dielectric layer 12 is already serving as a photo-stopping layer, hence no precuring process is performed on the first dielectric layer 12. Similarly, a photolithography process is then performed directly on the second dielectric layer 14, and a drilling process is performed on the first dielectric layer 12 to form the vias 20.

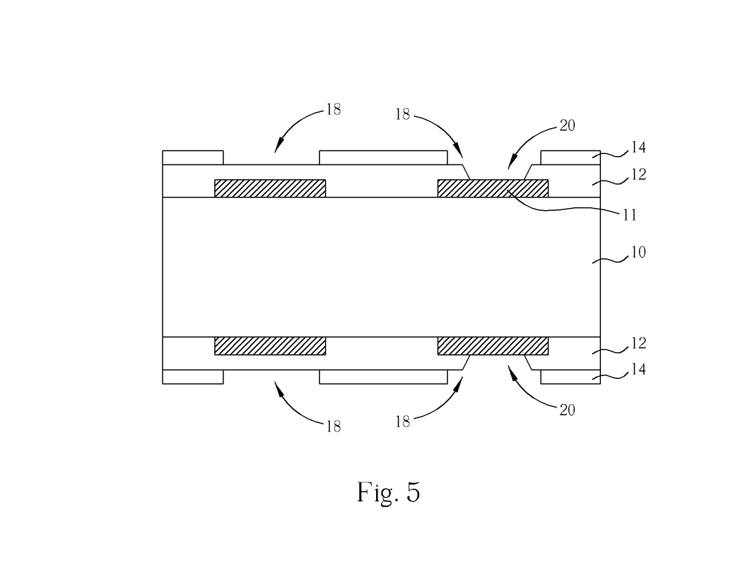

If the second dielectric layer 14 is comprised of non-photosensitive material, an etching process is performed utilizing the photoresist as a patterned resistive 16 to etch the second dielectric layer 14. However, when the first dielectric layer 12 and the second dielectric layer 14 are both comprised of the same material, a precuring process is first performed on the first dielectric layer 12 to turn the first dielectric layer 12 into an etching stop layer. Next, an etching process is performed to etch the second dielectric layer 14, in which the etching process will be stopped at the surface of the first dielectric layer 12. Next a drilling process is performed to the first dielectric layer 12 to form the vias 20, wherein the vias 20 are located at the openings 18 corresponding to the contact pads 11. And then removing the patterned resistive 16, as shown in FIG. 5. Preferably, the patterned resistive 16 is formed by various processes including: molding, coating, printing, sputtering, or non-electroplating and materials chosen from dry films, liquid photoresist, or metal masks. Lastly, when the first dielectric layer 12 and the second dielectric layer 14 are comprised of different material, a material not sensitive to the standard etching process is chosen to form the first dielectric layer 12 because the first dielectric layer 12 also serves as an etching stop layer. Next an etching process is performed to the second dielectric layer 14 and a drilling process is performed on the first dielectric layer 12. In this case, a drilling process is performed to the first dielectric layer 12 to form the vias 20, wherein the vias 20 are located at the openings 18 corresponding to the contact pads 11.

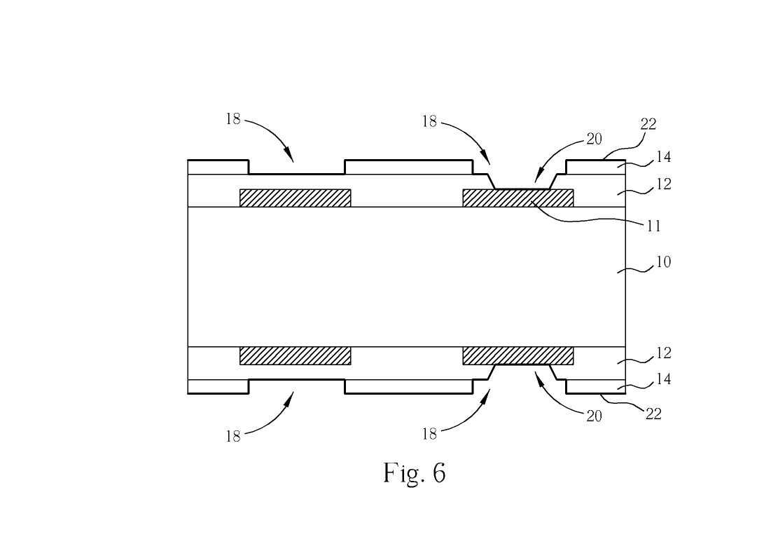

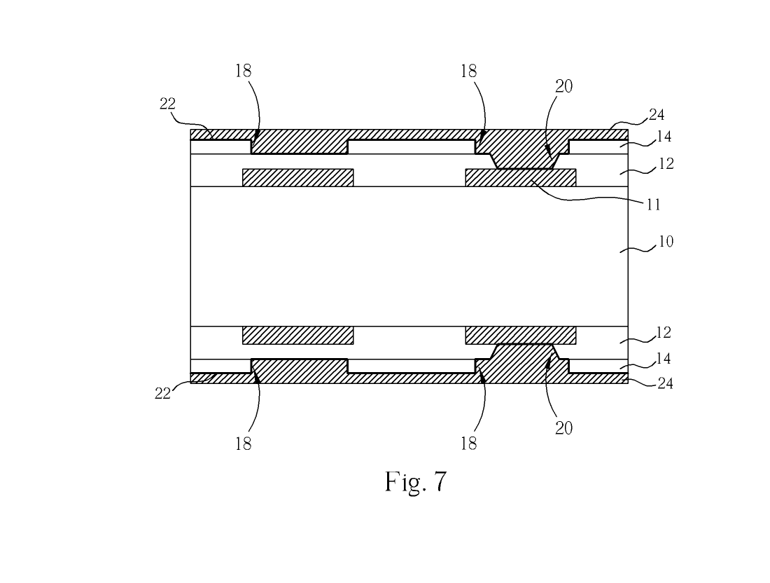

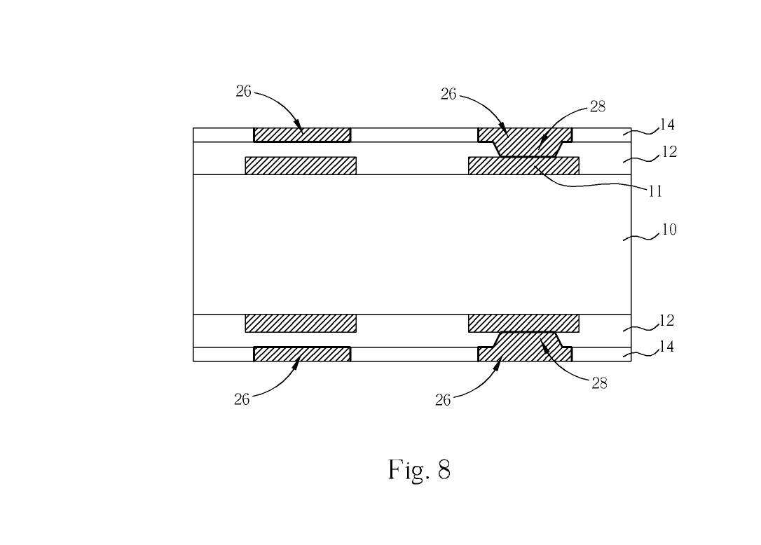

As shown in FIG. 6, a seed layer 22 is then formed over the surface of the second dielectric layer 14, each pattern opening 18 and each via 20. Preferably, the seed layer 22 is formed by various methods including: sputtering, electroless plating or chemical deposition. Additionally, the seed layer 22 can be comprised of conductive materials or conductive high polymers including: chromium, copper, tantalum, gold, silver, titanium, or nickel. Next, a conductive metal layer 24 is electroplated onto the seed layer 22 and into each pattern opening 18 and each vias 20, as shown in FIG. 7. Finally, an etching and planarizing process is performed to remove the seed layer 22 and conductive metal layer 24 on the surface of the second dielectric layer 14 to form circuits 26 and conductive vias 28, in which the conductive metal layer 24 disposed into each pattern opening 18 and each vias 20 is at the same level as the surface of the second dielectric layer 14, as shown in FIG. 8. It should be noted that the process shown in FIG. 1 though FIG. 8 can be performed repeatedly on both sides of the core substrate 10 to form a multi-layer circuit board.

As shown in FIG. 8, the present invention also discloses a build-up layer circuit board with fine pitches. The build-up layer circuit board includes a core substrate 10, in which the substrate includes a plurality of conductive pads 11 thereon; a first dielectric layer 12 disposed over the surface of the core substrate 10, in which the first dielectric layer 12 includes a plurality of vias corresponding to the conductive pads 11 of the core substrate 10, and the vias further include conductive vias 28 therein; and a second dielectric layer 14 disposed on the first dielectric layer 12, in which the second dielectric layer 14 includes a plurality of patterned openings, and the patterned openings further include conductive circuits 26 therein. The conductive circuits 26 are electrically connected to the conductive pads 11 through the conductive vias 28 and at least a separation is created for the conductive circuits 26 by utilizing the second dielectric layer 14.

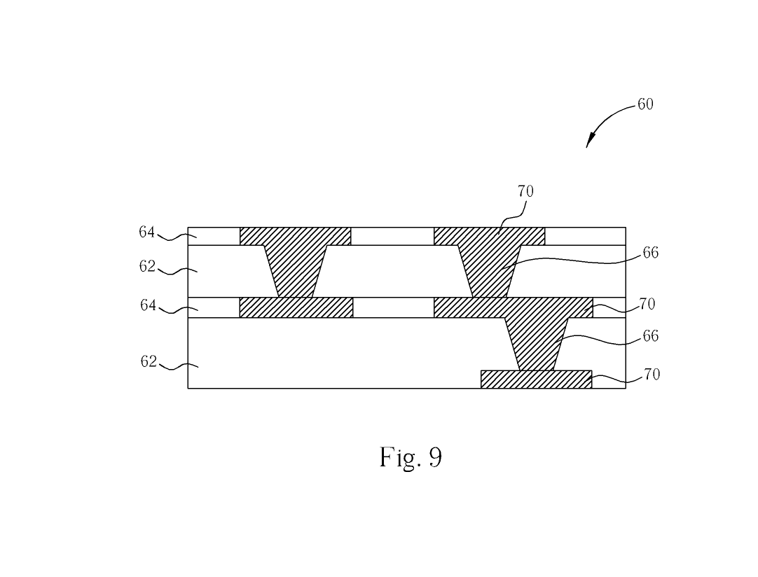

Please refer to FIG. 9. FIG. 9 is a perspective diagram showing the build-up layer structure 60 with fine pitches according to the present invention. As shown in FIG. 9, the build-up layer structure 60 with fine pitches includes a first dielectric layer 62, in which the first dielectric layer 62 includes a plurality of vias, and the vias further include conductive vias 66 therein. Additionally, a second dielectric layer 64 is formed over the surface of the first dielectric layer 62, in which the second dielectric layer 64 includes a plurality of patterned openings, and the patterned openings further include conductive circuits 70 therein. As shown in FIG. 9, the conductive circuits 70 are electrically connected to the conductive vias 66 and a separation is created for the conductive circuits 70 by utilizing the second dielectric layer 64. In addition to the build-up layer structure shown in FIG. 9, the first dielectric layer 62 and the second dielectric layer 64 can be formed repeatedly over one another forming a build-up circuit board with multi-layers.

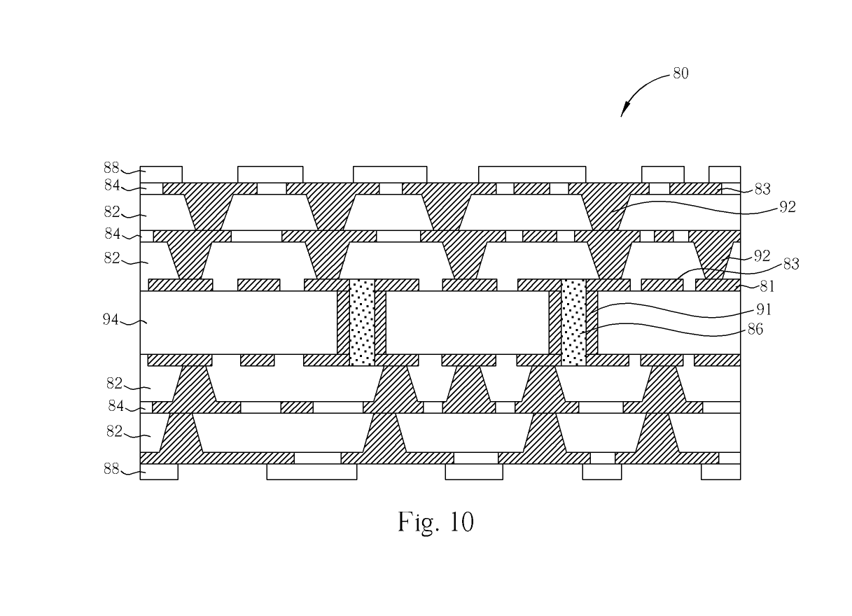

Please refer to FIG. 10. FIG. 10 is a perspective diagram showing the build-up circuit board 80 with fine pitches on both sides of the circuit board according to the present invention. As shown in FIG. 10, a core substrate 94 includes a plurality of plated through holes (PTH) 91, conductive pads 81, and conductive circuits 83, in which the plated through holes 91 are formed by mechanical drilling and electroplating processes. The plated through holes 91 also include a plugging material 86 therein, and each side of the core substrate 94 includes a first dielectric layer 82, in which the first dielectric layer 82 includes a plurality of vias corresponding to the conductive pads 81 of the core substrate 94, and the vias further include conductive vias 92 therein. Additionally, a second dielectric layer 84 is formed over the surface of the first dielectric layer 82, in which the second dielectric layer 84 includes a plurality of pattern openings and the pattern openings further includes conductive circuits 83 therein. The conductive circuits 83 are electrically connected to the conductive pads 81 through the conductive vias 92 and at least a separation is created for the conductive circuits 83 by utilizing the second dielectric layer 84. Lastly, the solder mask layers 88 are disposed on the outermost layers of the build-up circuit board 80 to serve as the protective layers.

In addition to the structure shown in FIG. 10, the first dielectric layer 82 and the second dielectric layer 84 can be formed repeatedly on one side or both sides of the core substrate 94 to achieve a multi-layer build-up circuit board with fine pitches.

In contrast to the conventional method, the present invention provides a method of forming a plurality of pattern openings and vias within a dielectric layer and depositing conductive metals into each pattern opening and via, thereby achieving a packaging substrate with much finer pitches, simplifying the fabrication process, lowering costs, and increasing the overall product yield. Additionally, the present invention is applicable to various circuit board packaging techniques, including: plastic ball grid array (PBGA), flip-chip chip scale package (FCCSP), chip scale package (CSP), flip-chip ball grid array (FCBGA), daughter card, module substrates, high density PWB, and substrates within embedded components.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a multi-layer circuit board with fine pitches comprising:
providing a core substrate, wherein the core substrate comprises a plurality of conductive pads thereon;
forming a first dielectric layer over the surface of the core substrate;
forming a second dielectric layer over the surface of the first dielectric layer;
forming a plurality of pattern openings within the second dielectric layer;
forming a plurality of vias within the first dielectric layer, wherein the vias are located at the openings corresponding to the contact pads;
forming a seed layer on the surface of the second dielectric layer, the pattern openings, and the vias;
electroplating a conductive layer on the seed layer for forming conductive circuits in each pattern openings and conductive vias in each vias; and
removing the electroplated conductive metal layer and the seed layer over the surface of the second dielectric layer for forming a separation for each conductive circuit at each patterned opening.

2. The method of claim 1, wherein the core substrate is comprised of a double layer substrate, a multi-layer substrate, an organic insulating substrate, an inorganic insulating substrate, a ceramic substrate, or a metal substrate.

3. The method of claim 1, wherein the first dielectric layer and the second dielectric layer are comprised of the same or different materials.

4. The method of claim 3, wherein the first dielectric layer and the second dielectric layer are comprised of photosensitive material, the method comprising:
performing a precuring process on the first dielectric layer for turning the first dielectric layer into a photo-stopping layer; and
performing a photolithography process on the second dielectric layer and a drilling process to the first dielectric layer.

5. The method of claim 3, wherein the first dielectric layer is comprised of non-photosensitive material and the second dielectric layer is comprised of photosensitive material, the method comprising:
performing a photolithography process on the second dielectric layer by utilizing the first dielectric layer as a photo-stopping layer; and
performing a drilling process on the first dielectric layer.

6. The method of claim 3, wherein the first dielectric layer and the second dielectric layer are comprised of the same non-photosensitive material, the method comprising:
performing a precuring process on the first dielectric layer for turning the first dielectric layer into an etching-stop layer; and performing an etching process to the second dielectric layer and a drilling process to the first dielectric layer.

7. The method of claim 3, wherein the first dielectric layer and the second dielectric layer are comprised of different non-photosensitive material, the method comprising:
choosing a material not sensitive to the etching process as the first dielectric layer to turn the first dielectric layer into an etching-stop layer; and
performing an etching process on the second dielectric layer and a drilling process to the first dielectric layer.

8. The method of claim 1, wherein the method can be performed repeatedly on one side or two sides of the core substrate to form a multi-layer circuit board.

9. A method of fabricating a multi-layer circuit board with fine pitches comprising;
providing a core substrate, wherein the core substrate comprises a plurality of conductive pads thereon;
providing a composite layer, wherein the composite layer comprises a first dielectric layer and a second dielectric layer;
laminating the first dielectric layer of the composite layer to the core substrate;
forming a plurality of pattern openings within the second dielectric layer;
forming a plurality of vias within the first dielectric layer, wherein the vias are located at the openings corresponding to the contact pads;
forming a seed layer on the surface of the second dielectric layer, the pattern openings, and the vias;
electroplating a conductive layer on the seed layer for forming conductive circuits in each pattern opening and conductive vias in each vias; and
removing the electroplated conductive metal layer and the seed layer over the surface of the second dielectric layer for forming a separation for each conductive circuit at each patterned opening.

10. The method of claim 9, wherein the core substrate is comprised of a double layer substrate, a multi-layer substrate, an organic insulating substrate, an inorganic insulating substrate, a ceramic substrate, or a metal substrate.

11. The method of claim 9, wherein the first dielectric layer and the second dielectric layer are comprised of the same or different materials.

12. The method of claim 11, wherein the first dielectric layer and the second dielectric layer are comprised of photosensitive material, the method comprising:
performing a precuring process to the first dielectric layer to turn the first dielectric layer into a photo-stopping layer; and
performing a photolithography process to the second dielectric layer and a drilling process to the first dielectric layer.

13. The method of claim 11, wherein the first dielectric layer is comprised of non-photosensitive material and the second dielectric layer is comprised of photosensitive material, the method comprising:
performing a photolithography process to the second dielectric layer utilizing the first dielectric layer as a photo-stopping layer; and
performing a drilling process to the first dielectric layer.

14. The method of claim 11, wherein the first dielectric layer and the second dielectric layer are comprised of the same non-photosensitive material, the method comprising:
performing a precuring process to the first dielectric to turn the first dielectric layer into an etching-stop layer; and performing an etching process to the second dielectric layer and a drilling process to the first dielectric layer.

15. The method of claim 11, wherein the first dielectric layer and the second dielectric layer are comprised of different non-photosensitive material, the method comprising:
choosing a material not sensitive to the etching process as the first dielectric layer for turning the first dielectric layer to an etching-stop layer; and
performing an etching process to the second dielectric layer and a drilling process to the first dielectric layer.

16. The method of claim 11, wherein the method can be performed repeatedly on one side or two sides of the core substrate to form a multi-layer substrate.

17. A build-up layer circuit board with fine pitches comprising:
a core substrate having a plurality of conductive pads thereon;
a first dielectric layer formed on the surface of the core substrate;
a plurality of conductive vias formed on the first dielectric layer, wherein the vias are corresponding to the contact pads;
a second dielectric layer formed on the surface of the first dielectric layer, wherein the second dielectric layer has a plurality of patterned openings and the patterned openings further include circuits therein; and
the circuits are electrically connected to the contact pads through the conductive vias.

18. The substrate structure of claim 17, wherein the core substrate is a double layer substrate, a multi-layer substrate, an organic insulating substrate, an inorganic insulating substrate, a ceramic substrate, or a metal substrate.

19. The substrate structure of claim 17, wherein the first dielectric layer and the second dielectric layer are the same material dielectric layers or different material dielectric layers.

20. The method of claim 17, wherein the method can be performed repeatedly on one side or two sides of the core substrate to form a multi-layer substrate.

21. A build-up layer circuit board with fine pitches comprising:
a first dielectric layer;
a plurality of conductive vias within the first dielectric layer, wherein the vias are located at the openings corresponding to the contact pads;
a second dielectric layer formed on the surface of the first dielectric layer; and
a plurality of conductive circuits within the second dielectric layer, wherein the conductive circuits are electrically connected to the conductive vias.

22. The substrate structure of claim 21, wherein the first dielectric layer and the second dielectric layer are the same material dielectric layers or different material dielectric layers.
